(19) United States
(12) Patent Application Publication
(10) Pub. No.: US 2017/0104033 A1
(43) Pub. Date: Apr. 13, 2017

(54) ARRAY SUBSTRATE AND MANUFACTURING METHOD FOR THE SAME

(71) Applicant: Shenzhen China Star Optoelectronics Technology Co., Ltd., Shenzhen, Guangdong (CN)

(72) Inventors: Chang-i SU, Shenzhen, Guangdong (CN); Hongyuan XU, Shenzhen, Guangdong (CN)

(73) Assignee: Shenzhen China Star Optoelectronics Technology Co., Ltd., Shenzhen, Guangdong (CN)

(21) Appl. No.: 14/893,523

(22) PCT Filed: Oct. 22, 2015
(86) PCT No.: PCT/CN2015/092552

§ 371 Date: Nov. 23, 2015

(30) Foreign Application Priority Data
Oct. 13, 2015 (CN) 201510657814.7

(51) Int. Cl. H01L 27/28; H01L 51/00; H01L 51/05

(52) U.S. Cl. CPC H01L 27/283; H01L 51/0541; H01L 51/0097; H01L 51/0018

(57) ABSTRACT

An array substrate and a manufacturing method for the same are disclosed. The manufacturing method includes a step of forming a top-gate type thin-film transistor including steps of forming a source electrode and a drain electrode on a substrate; sequentially and stackedly forming an organic semiconductor layer, a first insulation layer and a gate electrode on the source electrode and the drain electrode; and using the gate electrode as a hard mask, and utilizing an etching technology for patterning the first insulation layer and the organic semiconductor layer one by one. The top-gate type thin-film transistor which is manufactured by the above method and using the gate electrode as a hard mask for sequentially patterning the first insulation layer and the organic semiconductor layer is simple in the manufacturing process, and can prevent the organic semiconductor layer from damaging.

### BACKGROUND OF THE INVENTION

1. Field of the Invention

The present invention relates to a display field, and more particularly to an array substrate and a manufacturing method for the same.

2. Description of Related Art

A wearable device is a brand new development field for the display device. However, the current display device is a glass substrate display device, which cannot be bent effectively. Therefore, to develop a flexible display, a substrate that is totally different from a glass substrate is required such as a plastic substrate. On the other hand, the materials such as amorphous silicon, silicon carbide, silicon oxide which are used previously, because of the problems of mobility, hardness, curvature and manufacturing processing, cannot be applied in the flexible display device. Utilizing organic materials for a semiconductor layer and an insulation layer can effectively improve and develop a brand new display: a flexible display.

### SUMMARY OF THE INVENTION

The main technology problem solved by the present invention is to provide an array substrate and a manufacturing method for the same in a flexible display device.

In order to solve the above technology problem, a technology solution adopted by the present invention is: a manufacturing method for forming a top-gate type thin-film transistor of an array substrate, comprising steps of: forming a source electrode and a drain electrode on a substrate; forming a data line connected with the source electrode and a transmission pad connected with the drain electrode; sequentially and stackedly forming an organic semiconductor layer, a first insulation layer and a gate electrode on the source electrode and the drain electrode; and using the gate electrode as a hard mask, and utilizing an etching technology for patterning the first insulation layer and the organic semiconductor layer one by one.

Wherein, after the step of using the gate electrode as a hard mask, and utilizing an etching technology for patterning the first insulation layer and the organic semiconductor layer one by one, the manufacturing method further includes: forming a scanning line connected with the gate electrode; and forming a transparent electrode layer connected with the transmission pad.

Wherein, the step of forming a scanning line connected with the gate electrode includes: forming a second insulation layer on the gate electrode, wherein, the second insulation layer includes a first via hole corresponding to the gate electrode and a second via hole corresponding to the transmission pad; and forming the scanning line on the second insulation layer, and the scanning line passes through the first via hole to electrically connect with the gate electrode.

Wherein, the step of forming a transparent electrode layer connected with the transmission pad includes: forming a third insulation layer on the second insulation layer, and the third insulation layer has a third via hole formed in the second via hole; and forming a transparent electrode layer on the third insulation layer, and the transparent electrode layer passes through the second via hole to electrically connect with the transmission pad.

Wherein, the step of sequentially and stackedly forming an organic semiconductor layer, an insulation layer and a gate electrode on the source electrode and the drain electrode includes: depositing the organic semiconductor layer on the source electrode and the drain electrode; depositing the first insulation layer on the organic semiconductor layer; and depositing a gate metal layer on the first insulation layer, and utilizing a gate photomask process for patterning the gate metal layer in order to form the gate electrode.

In order to solve the above technology problem, another technology solution adopted by the present invention is: a manufacturing method for forming a top-gate type thin-film transistor of an array substrate, comprising steps of: forming a source electrode and a drain electrode on a substrate; sequentially and stackedly forming an organic semiconductor layer, a first insulation layer and a gate electrode on the source electrode and the drain electrode; and using the gate electrode as a hard mask, and utilizing an etching technology for patterning the first insulation layer and the organic semiconductor layer one by one.

Wherein, after the step of forming a source electrode and a drain electrode on a substrate, the manufacturing method further includes: forming a data line connected with the source electrode and a transmission pad connected with the drain electrode.

Wherein, after the step of using the gate electrode as a hard mask, and utilizing an etching technology for patterning the first insulation layer and the organic semiconductor layer one by one, the manufacturing method further includes: forming a scanning line connected with the gate electrode; and forming a transparent electrode layer connected with the transmission pad.

Wherein, the step of forming a scanning line connected with the gate electrode includes: forming a second insulation layer on the gate electrode, wherein, the second insulation layer includes a first via hole corresponding to the gate electrode and a second via hole corresponding to the transmission pad; and forming the scanning line on the second insulation layer, and the scanning line passes through the first via hole to electrically connect with the gate electrode.

Wherein, the step of forming a transparent electrode layer connected with the transmission pad includes: forming a third insulation layer on the second insulation layer, and the third insulation layer has a third via hole formed in the second via hole; and forming a transparent electrode layer on the third insulation layer, and the transparent electrode layer passes through the second via hole to electrically connect with the transmission pad.

Wherein, the etching technology is a dry etching.

Wherein, the step of sequentially and stackedly forming an organic semiconductor layer, an insulation layer and a gate electrode on the source electrode and the drain electrode includes: depositing the organic semiconductor layer on the source electrode and the drain electrode; depositing the first insulation layer on the organic semiconductor layer; and depositing a gate metal layer on the first insulation layer, and utilizing a gate photomask process for patterning the gate metal layer in order to form the gate electrode.

In order to solve the above technology problem, another technology solution adopted by the present invention is: an array substrate, comprising: a substrate; and a top-gate type thin-film transistor including a source electrode, a drain electrode, a gate electrode, an organic semiconductor layer and an insulation layer, wherein the source electrode and the drain electrode are disposed on the substrate and disposed at a same layer; the organic semiconductor layer, the insulation layer and the gate electrode are sequentially and stackedly disposed on the source electrode and the drain electrode; a patterning process for the organic semiconductor layer and the insulation layer is utilizing the gate electrode as a hard mask and through an etching.

Wherein, the substrate is a flexible substrate.

Wherein, the array substrate further includes a data line, a scanning line, a transmission pad and a transparent electrode layer; the scanning line is connected with the gate electrode; the data line is connected with the source electrode; the transmission pad is connected with the drain electrode and the transparent electrode layer; the data line and the transmission pad are manufactured by a same process that is different from the source electrode and the drain electrode; an etching resist ability of the data line and the transmission pad is better than the source electrode and the drain electrode.

The beneficial effect of the present invention is: comparing with the conventional art, the top-gate type thin-film transistor manufactured by the manufacturing method for the array substrate of the present invention and using the gate electrode as a hard mask for sequentially patterning the first insulation layer and the organic semiconductor layer is simple in the manufacturing process, and can prevent the organic semiconductor layer from damaging.

### BRIEF DESCRIPTION OF THE DRAWINGS

FIG. 1 is a flowchart of a manufacturing method for an array substrate according to a first embodiment of the present invention;

FIG. 2 is a flowchart of stackedly forming an organic semiconductor layer, an insulation layer and a gate electrode layer in the manufacturing method shown in FIG. 1;

FIG. 3 is a flowchart of a manufacturing method for an array substrate according to a second embodiment of the present invention;

FIG. 4A-4F is a schematic structure diagram of the array substrate in the manufacturing process of the manufacturing method shown in FIG. 3; and

FIG. 5 is a schematic structure diagram of the array substrate manufactured by the manufacturing method shown in FIG. 3.

### DETAILED DESCRIPTION OF THE PREFERRED EMBODIMENT

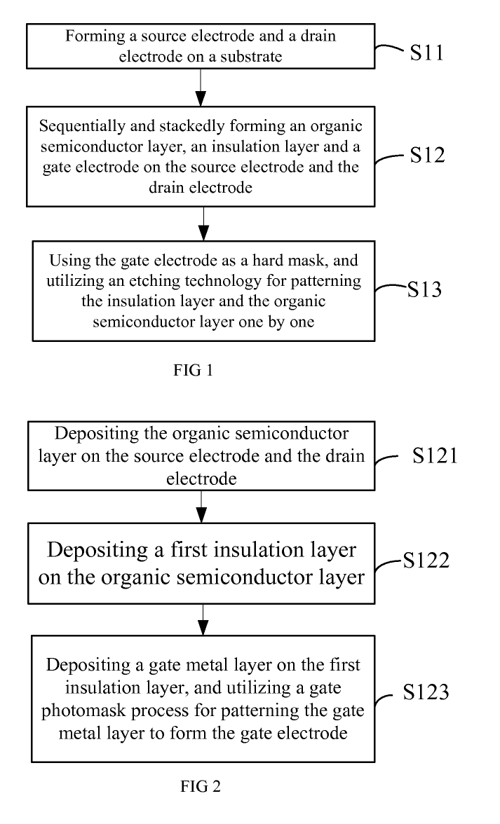

With reference to FIG. 1 and FIG. 2, the manufacturing method for an array substrate according to a first embodiment of the present invention includes a step of forming a top-gate type thin-film transistor, and the step of forming the top-gate type thin-film transistor specifically includes:

Step 11: forming a source electrode and a drain electrode on a substrate.

In the present step, preferably, the substrate is selected to have a better bending performance, that is, an easily bending substrate such that the manufacturing method for an array substrate of the present invention can be applied in a flexible display device. A substrate which has a better bending performance and can be applied in the flexible display device includes a plastic substrate, and so on. Of course, the present invention can also be applied on an unbendable display device, and the substrate is a glass substrate which has a poor bending performance.

The step of forming the source electrode and the drain electrode on the substrate specifically includes: depositing a first metal layer on the substrate, and using a first photomask process for patterning the first metal layer in order to form the source electrode and the drain electrode disposed at an interval.

Step S12: sequentially and stackedly forming an organic semiconductor layer, an insulation layer and a gate electrode on the source electrode and the drain electrode.

The present step specifically includes:

Step S121: depositing the organic semiconductor layer on the source electrode and the drain electrode.

The present step can also be understood as depositing the organic semiconductor layer which covers the source electrode and the drain electrode on the substrate.

Step S122: depositing a first insulation layer on the organic semiconductor layer.

When an insulation layer is applied in the flexible display device, if utilizing the materials such as amorphous silicon, silicon carbide, and silicon oxide, the problems of mobility, hardness, curvature and manufacturing process are existed. Therefore, preferably, the first insulation layer is an organic material layer.

Step S123: depositing a gate metal layer on the first insulation layer, and utilizing a gate photomask process for patterning the gate metal layer in order to form the gate electrode.

Because in the forming process of the source electrode and the drain electrode, one metal layer is deposited, in the forming process of the gate electrode in the present step, another metal layer is deposited. In the process of forming a top-gate type thin-film transistor, in order to corresponding to the first metal layer described foregoing, the gate metal layer is a second metal layer, and the gate photomask process is a second photomask process.

Step S13: using the gate electrode as a hard mask, and utilizing an etching technology for patterning the insulation layer and the organic semiconductor layer one by one.

Specifically, because the organic semiconductor layer is very easy to produce pollution by using a wet etching, the etching technology in the preset step is a dry etching technology. After forming the gate electrode, directly utilizing the gate electrode as a hard mask, and utilizing the dry etching that has an etching rate difference in metal and organic material in order to finish patterning. In other words, the gate electrode is a metal layer, and the gate electrode can resist the dry etching. However, the first insulation layer and the organic semiconductor layer cannot resist the dry etching. When using the gate electrode as the hard mask, the first insulation layer and the organic semiconductor layer located below the gate electrode can be reserved. The other portion of the first insulation layer and the organic semiconductor layer that is not protected by the gate electrode is etched and removed. After finishing the present step, the gate electrode, the first insulation layer and the organic semiconductor layer will be completely overlapped in a stacked direction of the gate electrode, the first insulation layer and the organic semiconductor layer.

Through above steps, the top-gate type thin-film transistor is finished.

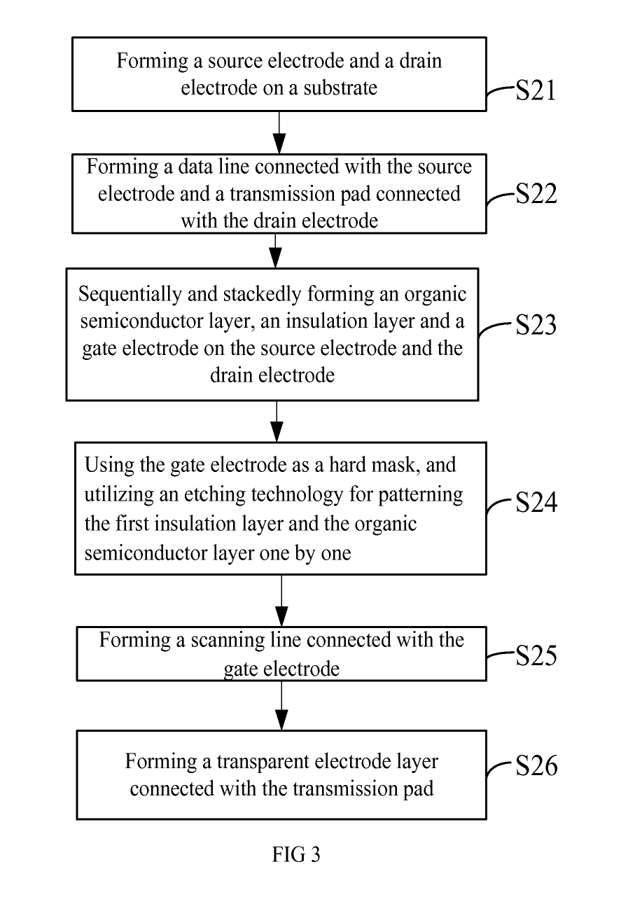

Of course, when manufacturing an array substrate, in addition to the thin-film transistor, building an electric connection between the thin-film transistor and an external circuit is also required. Specifically, with reference to FIG. 3, and FIG. 3 is a flowchart of a manufacturing method for an array substrate according to a second embodiment of the present invention. Specifically, the present embodiment includes:

Step S21: forming a source electrode and a drain electrode on a substrate.

In this step, preferably, the substrate is selected to have a better bending performance, that is, an easily bending substrate such that the manufacturing method for an array substrate of the present invention can be applied in a flexible display device. A substrate which has a better bending performance and can be applied in the flexible display device includes a plastic substrate, and so on. Of course, the present invention can also be applied on an unbendable display device, and the substrate is a glass substrate which has a poor bending performance.

The step of forming the source electrode and the drain electrode on the substrate specifically includes: depositing a first metal layer on the substrate, and using a first photomask process for patterning the first metal layer in order to form the source electrode and the drain electrode disposed at an interval. The first metal layer utilizes a material having a high conductive property.

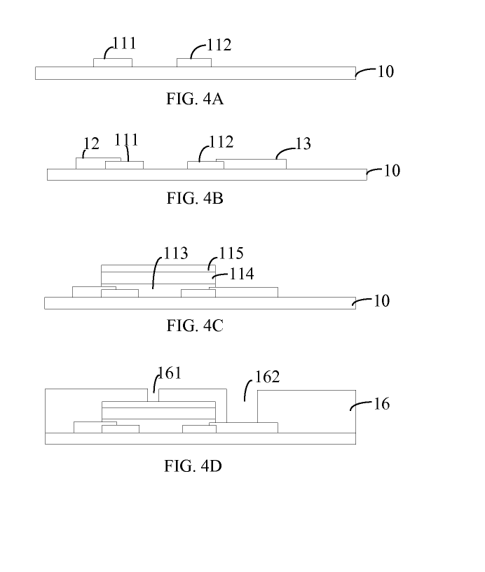

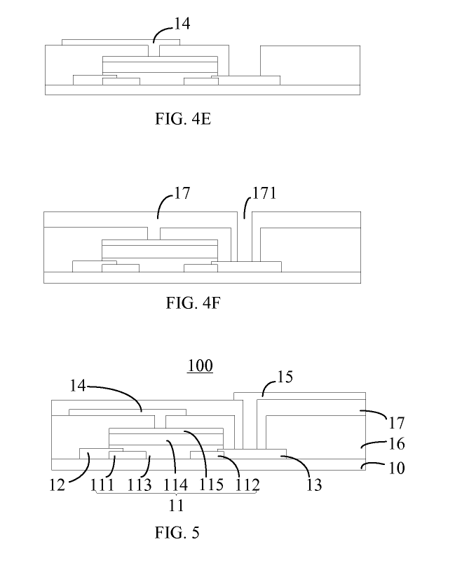

With reference to FIG. 4A, and FIG. 4A is a main schematic diagram of a source electrode 111 and a drain electrode 112 after performing a first photomask process to the first metal layer deposited on the substrate 10.

Step S22: forming a data line connected with the source electrode and a transmission pad connected with the drain electrode.

Specifically, depositing a second metal layer on the substrate, and using a second photomask process for patterning the second metal layer. After patterning, the data line connected with the source electrode and the transmission pad connected with the drain electrode are formed. For subsequent process, the material adopted at the second metal layer is different form the material adopted at the first metal layer. The second metal layer utilizes a material that has a better ability to resist etching.

With also reference to FIG. 4B, and FIG. 4B is a main schematic diagram of the data line 12 connected with the source electrode 11 and the transmission pad 13 connected with the drain electrode 112 after performing the second photomask process to the second metal layer depositing on the substrate 10.

Step S23: Sequentially and stackedly forming an organic semiconductor layer, an insulation layer and a gate electrode on the source electrode and the drain electrode.

The present step specifically includes:

Depositing the organic semiconductor layer on the source electrode and the drain electrode; depositing a first insulation layer on the organic semiconductor layer; depositing the gate metal layer on the first insulation layer, and using a gate photomask process for patterning the gate metal layer in order to form the gate electrode.

Comparing with the first metal layer and the second metal layer illustrated above, the gate metal layer deposited in the forming process of the gate electrode is a third metal layer. The gate photomask process is a third photomask process.

Step S24: using the gate electrode as a hard mask, and utilizing an etching technology for patterning the first insulation layer and the organic semiconductor layer one by one.

Specifically, because the organic semiconductor layer is very easy to produce pollution by using a wet etching, the etching technology in the preset step is a dry etching technology. After forming the gate electrode, directly utilizing the gate electrode as a hard mask, and utilizing the dry etching that has an etching rate difference in metal and organic material in order to finish patterning. In other words, the gate electrode is a metal layer, and the gate electrode can resist the dry etching. However, the first insulation layer and the organic semiconductor layer cannot resist the dry etching. When using the gate electrode as the hard mask, the first organic layer and the organic semiconductor layer located below the gate electrode can be reserved. The other portion of the first organic layer and the organic semiconductor layer that is not protected by the gate electrode is etched and removed. After finishing the present step, the gate electrode, the first insulation layer and the semiconductor layer will be completely overlapped in a stacked direction of the gate electrode, the first insulation layer and the semiconductor layer.

Furthermore, because the data line 12 and the transmission pad 13 select the material which has a better ability to resist etching in order to avoid that the first insulation layer and the organic semiconductor layer is etched in the patterning process.

With also reference to FIG. 4C, and FIG. 4C shows the first insulation layer 114 and the organic semiconductor layer 113 after patterning the first insulation layer and the organic semiconductor layer by using a dry etching through using the gate electrode 115 as the hard mask.

Step S25: forming a scanning line connected with the gate electrode.

The present step specifically includes: forming a second insulation layer on the gate electrode, wherein, the second insulation layer includes a first via hole corresponding to the gate electrode and a second via hole corresponding to the transmission pad; forming the scanning line on the second insulation layer, and the scanning line passes through the first via hole to electrically connect with the gate electrode.

The specific process for forming the second insulation layer is: depositing a layer of insulation material, patterning the layer of insulation material through a fourth photomask process. After patterning, the second insulation layer 16 having the first via hole 161 connected with the gate electrode 115 and the second via hole 162 connected with the transmission pad 13 as shown in FIG. 4D is obtained.

The process for forming the scanning line on the second insulation layer specifically is: depositing a fourth metal layer on the second insulation layer, and patterning the fourth metal layer through a fifth photomask process. After patterning, the scanning line 14 connected with the gate electrode 115 as shown in FIG. 4E is obtained.

Step S26: forming a transparent electrode layer connected with the transmission pad.

The present step specifically includes: forming a third insulation layer on the second insulation layer, and the third insulation layer has a third via hole formed in the second via hole; forming a transparent electrode layer on the third insulation layer, and the transparent electrode layer passes through the second via hole to electrically connect with the transmission pad.

The process for forming the third insulation layer specifically is: depositing a layer of insulation material on the second insulation layer and the scanning line, and patterning the layer of the insulation material through a sixth photomask process. After patterning, the third insulation layer 17 having the third via hole 171 located in the second via hole 162 and connecting with the transmission pad 13 is obtained.

The process for forming the transparent electrode layer is specifically: depositing a transparent electrode layer on the third insulation layer, and patterning the transparent electrode layer through a seventh photomask process. After patterning, an array substrate as shown in FIG. 5 is obtained.

Comparing with the conventional art, the top-gate type thin-film transistor manufactured by the manufacturing method for the array substrate of the present invention and using the gate electrode as a hard mask for sequentially patterning the first insulation layer and the organic semiconductor layer is simple in the manufacturing process, and can prevent the organic semiconductor layer from damaging. Furthermore, utilizing the dry etching that has an etching rate difference in metal material and organic material in order to finish patterning in order to avoid pollution to the organic semiconductor material. The source electrode and the drain electrode utilized a high conductive metal material, the data line and the transmission pad utilizes a material having a better etching resist ability, which can ensure that the thin-film transistor has better conductivity, and avoid damage for the data line and the transmission pad in the patterning process of the organic semiconductor layer.

With reference to FIG. 5, the present invention further provides an array substrate 100. The array substrate 100 is manufactured by the manufacturing method described foregoing.

The array substrate 100 includes a substrate 10, a thin-film transistor 11, a data line 12, a transmission pad 13, a scanning line 14 and a transparent electrode layer 15. Wherein, the thin-film transistor 11 is a top-gate type thin-film transistor. The thin-film transistor 11 includes a source electrode 111, a drain electrode 112, a gate electrode 115, an organic semiconductor layer 113 and an insulation layer 114. The source electrode 111 and the drain electrode 112 are disposed on the substrate 10 and disposed at a same layer. The organic semiconductor layer 113, the insulation layer 114 and the gate electrode 115 are sequentially and stackedly disposed on the source electrode 111 and the drain electrode 112. A patterning process for the organic semiconductor layer 113 and the insulation layer 114 is utilizing the gate electrode 115 as a hard mask and through a dry etching. Preferably, the substrate 10 is a flexible substrate and the insulation layer is an organic material. The array substrate 100 of the present invention can be applied in an organic display panel, an electro-phoretic display, a flexible touch panel or a flexible sensor, and so on.

The scanning line 14 is connected with the gate electrode 115. The data line 12 is connected with the source electrode 111. The transmission pad 13 is connected with the drain electrode 112 and the transparent electrode layer 15. The data line 12 and the transmission pad 13 are manufactured by a same process that is different from a process for manufacturing the source electrode and the drain electrode. Each of the source electrode 111 and the drain electrode 112 has a better conductive ability. An etching resist ability of the data line 12 and the transmission pad 13 is better than the source electrode and the drain electrode.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A manufacturing method for forming a top-gate type thin-film transistor of an array substrate, comprising steps of:
forming a source electrode and a drain electrode on a substrate;
forming a data line connected with the source electrode and a transmission pad connected with the drain electrode;
sequentially and stackedly forming an organic semiconductor layer, a first insulation layer and a gate electrode on the source electrode and the drain electrode; and
using the gate electrode as a hard mask, and utilizing an etching technology for patterning the first insulation layer and the organic semiconductor layer one by one.

2. The manufacturing method according to claim 1, wherein, after the step of using the gate electrode as a hard mask, and utilizing an etching technology for patterning the first insulation layer and the organic semiconductor layer one by one, the manufacturing method further includes:
forming a scanning line connected with the gate electrode; and
forming a transparent electrode layer connected with the transmission pad.

3. The manufacturing method according to claim 2, wherein, the step of forming a scanning line connected with the gate electrode includes:
forming a second insulation layer on the gate electrode, wherein, the second insulation layer includes a first via hole corresponding to the gate electrode and a second via hole corresponding to the transmission pad; and
forming the scanning line on the second insulation layer, and the scanning line passes through the first via hole to electrically connect with the gate electrode.

4. The manufacturing method according to claim 3, wherein, the step of forming a transparent electrode layer connected with the transmission pad includes:
forming a third insulation layer on the second insulation layer, and the third insulation layer has a third via hole formed in the second via hole; and
forming a transparent electrode layer on the third insulation layer, and the transparent electrode layer passes through the second via hole to electrically connect with the transmission pad.

5. The manufacturing method according to claim 1, wherein, the step of sequentially and stackedly forming an organic semiconductor layer, an insulation layer and a gate electrode on the source electrode and the drain electrode includes:
depositing the organic semiconductor layer on the source electrode and the drain electrode;
depositing the first insulation layer on the organic semiconductor layer; and
depositing a gate metal layer on the first insulation layer, and utilizing a gate photomask process for patterning the gate metal layer in order to form the gate electrode.

6. A manufacturing method for forming a top-gate type thin-film transistor of an array substrate, comprising steps of:
forming a source electrode and a drain electrode on a substrate;
sequentially and stackedly forming an organic semiconductor layer, a first insulation layer and a gate electrode on the source electrode and the drain electrode; and
using the gate electrode as a hard mask, and utilizing an etching technology for patterning the first insulation layer and the organic semiconductor layer one by one.

7. The manufacturing method according to claim 6, wherein, after the step of forming a source electrode and a drain electrode on a substrate, the manufacturing method further includes:
forming a data line connected with the source electrode and a transmission pad connected with the drain electrode.

8. The manufacturing method according to claim 7, wherein, after the step of using the gate electrode as a hard mask, and utilizing an etching technology for patterning the first insulation layer and the organic semiconductor layer one by one, the manufacturing method further includes:
forming a scanning line connected with the gate electrode; and
forming a transparent electrode layer connected with the transmission pad.

9. The manufacturing method according to claim 8, wherein, the step of forming a scanning line connected with the gate electrode includes:
forming a second insulation layer on the gate electrode, wherein, the second insulation layer includes a first via hole corresponding to the gate electrode and a second via hole corresponding to the transmission pad; and
forming the scanning line on the second insulation layer, and the scanning line passes through the first via hole to electrically connect with the gate electrode.

10. The manufacturing method according to claim 9, wherein, the step of forming a transparent electrode layer connected with the transmission pad includes:
forming a third insulation layer on the second insulation layer, and the third insulation layer has a third via hole formed in the second via hole; and
forming a transparent electrode layer on the third insulation layer, and the transparent electrode layer passes through the second via hole to electrically connect with the transmission pad.

11. The manufacturing method according to claim 6, wherein, the etching technology is a dry etching.

12. The manufacturing method according to claim 6, wherein, the step of sequentially and stackedly forming an organic semiconductor layer, an insulation layer and a gate electrode on the source electrode and the drain electrode includes:
depositing the organic semiconductor layer on the source electrode and the drain electrode;
depositing the first insulation layer on the organic semiconductor layer; and
depositing a gate metal layer on the first insulation layer, and utilizing a gate photomask process for patterning the gate metal layer in order to form the gate electrode.

13. An array substrate, comprising:
a substrate; and
a top-gate type thin-film transistor including a source electrode, a drain electrode, a gate electrode, an organic semiconductor layer and an insulation layer, wherein the source electrode and the drain electrode are disposed on the substrate and disposed at a same layer; the organic semiconductor layer, the insulation layer and the gate electrode are sequentially and stackedly disposed on the source electrode and the drain electrode; a patterning process for the organic semiconductor layer and the insulation layer is utilizing the gate electrode as a hard mask and through an etching.

14. The array substrate according to claim 13, wherein, the substrate is a flexible substrate.

15. The array substrate according to claim 13, wherein, the array substrate further includes a data line, a scanning line, a transmission pad and a transparent electrode layer; the scanning line is connected with the gate electrode; the data line is connected with the source electrode; the transmission pad is connected with the drain electrode and the transparent electrode layer; the data line and the transmission pad are manufactured by a same process that is different from the source electrode and the drain electrode; an etching resist ability of the data line and the transmission pad is better than the source electrode and the drain electrode.
